(19) United States
(12) Patent Application Publication
(10) Pub. No.: US 2020/0176234 A1
(43) Pub. Date: Jun. 4, 2020

(54) HIGH-POWER RESONANCE PULSE AC HEDP SPUTTERING SOURCE AND METHOD FOR MATERIAL PROCESSING

(71) Applicant: IonQuest Corp., Mansfield, MA (US)

(72) Inventors: Bassam Hanna Abraham, Millis, MA (US); Roman Chistyakov, North Andover, MA (US)

(73) Assignee: IonQuest Corp., Mansfield, MA (US)

(21) Appl. No.: 16/025,928

(22) PCT Filed: Aug. 24, 2017
(86) PCT No.: PCT/US2017/048438

§ 371 Date: Jul. 2, 2018

Related U.S. Application Data
(60) Provisional application No. 62/482,993, filed on Apr. 7, 2017.

(51) Int. Cl. H01J 37/34; C23C 14/35; C23C 14/34

(52) U.S. Cl. CPC H01J 37/3405; H01J 37/3467; H01J 37/342; H01J 37/3423; C23C 14/3485; C23C 14/35; C23C 14/3407; C23C 14/345; H01J 37/3426

(57) ABSTRACT

A method of sputtering using a high energy density plasma (HEDP) magnetron includes configuring an anode and cathode target magnet assembly in a vacuum chamber with a sputtering cathode target and substrate, applying regulated unipolar voltage pulses to a tunable pulse forming network, and adjusting amplitude and frequency of the unipolar voltage pulses to cause a resonance mode associated with the tunable pulse forming network and an output AC waveform generated from the pulse forming network. The output AC waveform is operatively coupled to the sputtering cathode target, and the output AC waveform includes a negative voltage exceeding the amplitude of the unipolar voltage pulses during sputtering discharge of the HEDP magnetron. An increase in the amplitude of the unipolar voltage pulses causes a constant amplitude of the negative voltage of the output AC waveform in response to the pulse forming network being in the resonance mode, thereby causing the HEDP magnetron sputtering discharge to form the layer on the substrate. A corresponding apparatus and computer-readable medium are disclosed.

### CROSS-REFERENCE TO RELATED APPLICATIONS

This application is a continuation-in-part application of International Application No. PCT/US17/48438, filed Aug. 24, 2017, which claims the benefit of U.S. Provisional Application No. 62/482,993, filed Apr. 7, 2017, the disclosures of which are incorporated by reference herein in their entireties.

### BACKGROUND

### Field

The disclosed embodiments generally relate to a high energy density plasma (HEDP) magnetically enhanced sputtering source and a method for sputtering hard thin films on a surface of a substrate.

### SUMMARY

The disclosed embodiments relate to a high energy density plasma (HEDP) magnetically enhanced sputtering source, apparatus, and method for sputtering hard coatings in the presence of high-power pulse asymmetrical alternating current (AC) voltage waveforms. The high-power pulse asymmetric AC voltage waveform is generated by having a regulated voltage source with variable power feeding a regulated voltage to the high-power pulse supply with programmable pulse voltage duration and pulse voltage frequency producing at its output a train of regulated amplitude unipolar negative voltage pulses with programmed pulse frequency and duration and supplying these pulses to a tunable pulse forming network (PFN) including a plurality of inductors and capacitors for pulse applications connected in a specific format coupled to a magnetically enhanced sputtering source. By adjusting the pulse voltage amplitude, duration, and frequency of the unipolar negative voltage pulses and tuning the values of the inductors and capacitors in the PFN coupled to a magnetically enhanced sputtering source, a resonance pulsed asymmetric AC discharge is achieved.

Another method to produce a resonance pulsed asymmetric AC discharge is to have fixed unipolar pulse power supply parameters (amplitude, frequency, and duration) feeding a pulse forming network, in which the numerical values of the inductors and capacitors, as well as the configuration can be tuned to achieve the desired resonance values on the HEDP source to form a layer on the substrate. The tuning of the PFN can be done manually with test equipment, such as an oscilloscope, voltmeter and current meter or other analytical equipment; or electronically with a built-in software algorithm, variable inductors, variable capacitors, and data acquisition circuitry. The negative voltage from the pulse asymmetric AC voltage waveform generates high density plasma from feed gas atoms and sputtered target material atoms between the cathode sputtering target and the anode of the magnetically enhanced sputtering source. The positive voltage from the pulse asymmetrical AC voltage waveform attracts plasma electrons to the cathode sputtering area and generates positive plasma potential. The positive plasma potential accelerates gas and sputtered target material ions from the cathode sputtering target area towards the substrate that improve deposition rate and increase ion bombardment on the substrate. The reverse electron current during positive voltage can be up to 50% from the discharge current during negative voltage.

In some embodiments, the magnetically enhanced sputtering source is a hollow cathode magnetron. The hollow cathode magnetron includes a hollow cathode sputtering target, and the tunable PFN that has a plurality of capacitors and inductors. The resonance mode associated with the tunable PFN is a function of the input unipolar voltage pulse amplitude, duration, and frequency generated by the high-power pulse power supply, inductance, resistance and capacitance of the hollow cathode magnetron or any other magnetically enhanced device, the inductance, capacitance, and resistance of the cables between the tunable PFN and hollow cathode magnetron, and a plasma impedance of the hollow cathode magnetron sputtering source itself as well as the sputtered target material.

In some embodiments, rather than the hollow cathode magnetron, a cylindrical magnetron is connected to an output of the tunable PFN. In some embodiments, rather than the hollow cathode magnetron, a magnetron with flat target is connected to the output of the tunable PFN. In the resonance mode, the output negative voltage amplitude of the high-power pulse voltage mode asymmetrical AC waveform on the magnetically enhanced device exceeds the negative voltage amplitude of the input unipolar voltage pulses into the tunable PFN by 1.1-5 times. The unipolar negative high-power voltage output can be in the range of 400V-5000V. In the resonance mode, the absolute value of the negative voltage amplitude of the asymmetrical AC waveform can be in the range of 750-10000 V. In the resonance mode, the output positive voltage amplitude of the asymmetrical AC waveform can be in the range of 100-5000 V. In some cases, the resonance mode of the negative voltage amplitude of the output AC voltage waveform can reach a maximum absolute value while holding all other component parameters (such as the pulse generator output, PFN values, cables and HEDP source) constant, wherein a further increase of the input voltage to the tunable PFN does not result in a voltage amplitude increase on the HEDP source, but rather an increase in the duration of the negative pulse in the asymmetric AC voltage waveform on the HEDP source.

Sputtering processes are performed with a magnetically and electrically enhanced HEDP plasma source positioned in a vacuum chamber. As mentioned above, the plasma source can be any magnetically enhanced sputtering source with a different shape of sputtering cathode target. Magnetic enhancement can be performed with electromagnets, permanent magnets, stationary magnets, moveable magnets, and/or rotatable magnets. In the case of a magnetron sputtering source, the magnetic field can be balanced or unbalanced. A typical power density of the HEDP sputtering process during a negative portion of the high voltage AC waveform is in the range of 0.1-20 kW/cm². A typical discharge current density of the HEDP sputtering process during a negative portion of the high voltage AC waveform is in the range of 0.1-20 A/cm². In the case of the hollow cathode magnetron sputtering source, the magnetic field lines form a magnetron configuration on a bottom surface of the hollow cathode target from the hollow cathode magnetron. Magnetic field lines are substantially parallel to the bottom surface of the hollow cathode target and partially terminate on the bottom surface and side walls of the hollow cathode target. The height of the side walls can be in the range of 5-100 mm. Due to the presence of side walls on the hollow cathode target, electron confinement is significantly improved when compared with a flat target in accordance with the disclosed embodiments. In some embodiments, an additional magnet assembly is positioned around the walls of the hollow cathode target. In some embodiments, there is a magnetic coupling between additional magnets and a magnetic field forms a magnetron configuration.

Since the high-power resonance asymmetric AC voltage waveform can generate HEDP plasma and, therefore, significant power on the magnetically enhanced sputtering source, the high-power resonance asymmetric AC voltage waveform is pulsed in programmable bursts to prevent damage to the magnetically enhanced sputtering source from excess average power. The programmable duration of the high-power resonance asymmetric AC voltage waveforms pulse bursts can be in the range of 0.1-100 ms. The frequency of the programmable high-power resonance asymmetric AC voltage waveforms pulse bursts can be in the range of 1 Hz-10000 Hz. In some embodiments, the high-power resonance asymmetric AC voltage waveform is continuous or has a 100% duty cycle assuming the HEDP plasma source can handle the average power. The frequency of the pulsed high-power resonance asymmetric AC voltage waveform inside the programmable pulse bursts can be programmed in the range of 100 Hz-400 kHz with a single frequency or mixed frequency.

The magnetically enhanced HEDP sputtering source includes a magnetron with a sputtering cathode target, an anode, a magnet assembly, a regulated voltage source connected to a high-power pulsed power supply with programmable output pulse voltage amplitude, frequency, and duration. The pulsed power supply is connected to the input of the tunable PFN, and the output of the tunable PFN is connected to the sputtering cathode target on the magnetically enhanced sputtering source. The tunable PFN, in resonance mode, generates the high-power resonance asymmetrical AC voltage waveforms and provides HEDP on the magnetically enhanced sputtering source.

The magnetically enhanced high-power pulse resonance asymmetric AC HEDP sputtering source may include a hollow cathode magnetron with a hollow cathode sputtering target, a second magnet assembly positioned around the side walls of the hollow cathode target, an electrical switch positioned between the tunable PFN and hollow cathode magnetron with a flat sputtering target rather than a hollow cathode shape, and a magnetic array with permanent magnets, electromagnets, or a combination thereof.

The magnetically enhanced high-power pulse resonance asymmetric AC HEDP sputtering apparatus includes a magnetically enhanced HEDP sputtering source, a vacuum chamber, a substrate holder, a substrate, a feed gas mass flow controller, and a vacuum pump.

The magnetically enhanced high-power pulse resonance asymmetric AC HEDP sputtering apparatus may include one or more electrically and magnetically enhanced HEDP sputtering sources, substrate heater, controller, computer, gas activation source, substrate bias power supply, matching network, electrical switch positioned between the tunable PFN and magnetically enhanced HEDP sputtering source, and a plurality of electrical switches connected with a plurality of magnetically enhanced high-power pulse resonance asymmetric AC HEDP sputtering sources and output of the tunable PFN.

A method of providing high-power pulse resonance asymmetric AC HEDP film sputtering includes positioning a magnetically enhanced sputtering source inside a vacuum chamber, connecting the cathode target to the output of the tunable PFN that, in resonance mode, generating the high-power asymmetrical AC waveform, positioning a substrate on a substrate holder, providing feed gas, programming voltage pulses frequency and duration, adjusting pulse voltage amplitude of the programmed voltage pulses with fixed frequency and duration feeding the tunable PFN, generating the output high voltage asymmetrical AC waveform with a negative voltage amplitude that exceeds the negative voltage amplitude of the voltage pulses in the resonance mode, thereby resulting in a high-power pulse resonance asymmetric AC HEDP discharge.

The method of magnetically enhanced high-power pulse resonance asymmetric AC HEDP film sputtering may include positioning an electrical switch between the hollow cathode magnetron and the tunable PFN that, in resonance mode, generates the high voltage asymmetrical AC waveform, applying heat to the substrate or cooling down the substrate, applying direct current (DC) or radio frequency (RF) continuously and/or using a pulse bias voltage to the substrate holder to generate a substrate bias, connecting the tunable PFN that, in resonance mode, generates the high voltage asymmetrical AC waveform simultaneously to the plurality of hollow cathode magnetrons or magnetrons with flat targets, and igniting and sustaining simultaneously HEDP in the plurality of the hollow cathode magnetron.

The disclosed embodiments include a method of sputtering a layer on a substrate using a high-power pulse resonance asymmetric AC HEDP magnetron. The method includes configuring an anode and a cathode target magnet assembly to be positioned in a vacuum chamber with a sputtering cathode target and the substrate, applying high-power negative unipolar voltage pulses with regulated amplitude and programmable duration and frequency to a tunable PFN, wherein the tunable PFN includes a plurality of inductors and capacitors, and adjusting an amplitude associated with the unipolar voltage pulses with programmed duration and frequency to cause a resonance mode associated with the tunable pulse forming network to produce an output high-power pulse resonance asymmetric AC on the HEDP sputtering source. The output high-power pulse resonance asymmetric AC voltage waveform from the tunable PFN is operatively coupled to the HEDP sputtering cathode target, and the output high-power pulse resonance asymmetric AC voltage waveform includes a negative voltage exceeding or equal to the amplitude of the input unipolar voltage pulses coming to the tunable PFN during the resonance mode and sputtering discharge of the HEDP magnetron. With all conditions fixed, any further increase of the amplitude of the unipolar voltage pulses causes only an increase in the duration of the maximum value of the negative voltage amplitude of the output high-power asymmetric AC voltage waveform in response to the pulse forming network being in the resonance mode, thereby causing the HEDP magnetron sputtering discharge to form the layer on the substrate.

The disclosed embodiments further include an apparatus that sputters a layer on a substrate using a high-power pulse resonance asymmetric AC HEDP magnetron. The apparatus includes an anode, cathode target magnet assembly, regulated high voltage source with variable power, high-power pulse power supply with programmable voltage pulse duration and frequency power supply, and a tunable PFN. The anode and cathode target magnet assembly are configured to be positioned in a vacuum chamber with a sputtering cathode target and the substrate. The high-power pulse power supply generates programmable unipolar negative voltage pulses with defined amplitude, frequency, and duration. The tunable pulse forming network includes a plurality of inductors and capacitors, and the amplitude of the voltage pulses are adjusted to be in the resonance mode associated with the tunable PFN and magnetically enhanced sputtering source for specific programmed pulse parameters, such as amplitude, frequency and duration of the unipolar voltage pulses. The output of the tunable PFN is operatively coupled to the sputtering cathode target, and the output of the tunable PFN in the resonance mode generates a high-power resonance asymmetric AC voltage waveform that includes a negative voltage exceeding the amplitude of the input to tunable PFN unipolar voltage pulses. An AC voltage waveform sustains plasma and forms high-power pulse resonance asymmetric AC HEDP magnetron sputtering discharge, thereby causing the HEDP magnetron sputtering discharge to form the layer of the sputtered target material on the substrate.

The disclosed embodiments also include a computer-readable medium storing instructions that, when executed by a processing device, perform a method of sputtering a layer on a substrate using a high energy density plasma (HEDP) magnetron, wherein the operations include configuring an anode and a cathode target magnet assembly to be positioned in a vacuum chamber with a sputtering cathode target and the substrate, applying regulated amplitude unipolar voltage pulses with programmed frequency and duration to the tunable PFN, wherein the pulse forming network includes a plurality of inductors and capacitors, and adjusting a pulse voltage for programmed voltage pulses frequency and duration to cause a resonance mode associated with the tunable PFN. The output asymmetric AC voltage waveform is operatively coupled to the sputtering cathode target, and the output asymmetric AC voltage waveform includes a negative voltage exceeding the amplitude of the regulated unipolar voltage pulses amplitude with programmed frequency and duration during sputtering discharge of the HEDP magnetron. A further increase in the amplitude of the regulated unipolar voltage pulses with programmed frequency and duration causes a constant amplitude of the negative voltage of the output AC waveform in response to the pulse forming network being in the resonance mode, thereby causing the HEDP magnetron sputtering discharge to form the layer on the substrate.

Other embodiments will become apparent from the following detailed description considered in conjunction with the accompanying drawings. It is to be understood, however, that the drawings are designed as an illustration only and not as a definition of the limits of any of the embodiments.

### BRIEF DESCRIPTION OF THE DRAWINGS

The following drawings are provided by way of example only and without limitation, wherein like reference numerals (when used) indicate corresponding elements throughout the several views, and wherein:

FIG. 1 (a) shows an illustrative view of a train of output negative unipolar voltage pulses with amplitude V1 and frequency f1 from a high-power pulse supply with programmable pulse voltage duration and pulse voltage frequency;

FIG. 1 (b) shows an illustrative view of an output resonance asymmetrical AC voltage waveform with a duration of negative voltage τ1 from a tunable pulse forming network (PFN);

FIG. 1 (c) shows an illustrative view of a train of output negative unipolar voltage pulses with amplitude V2 and frequency f1 from a high-power pulse supply with programmable pulse voltage duration and pulse voltage frequency;

FIG. 1 (d) shows an illustrative view of the output resonance asymmetrical AC voltage waveform with a duration of negative voltage τ2 from the tunable PFN;

FIG. 1 (e) shows an illustrative view of the output resonance asymmetrical AC voltage waveform with three oscillations from the tunable PFN;

FIG. 1 (f) shows an illustrative view of the output resonance asymmetrical AC current waveform with three oscillations from the PFN;

FIG. 1 (g) shows an illustrative cross-sectional view of components and magnetic field lines of a magnetically enhanced HEDP sputtering source with a stationary cathode target magnetic array;

FIG. 1 (h) shows an illustrative cross-sectional view of a hollow cathode target;

FIG. 2 (a) shows an illustrative circuit diagram of the high-power pulse resonance AC power supply;

FIG. 2 (b) shows an illustrative view of a train of unipolar voltage pulses with frequency f3 and amplitude V3 applied to the tunable PFN, and an output voltage waveform from the tunable PFN without a resonance mode in the tunable PFN;

FIG. 2 (c) shows an illustrative view of a train of unipolar voltage pulses with frequency f4 and amplitude V4 applied to the tunable PFN, and an output voltage waveform from the tunable PFN in a partial resonance mode;

FIG. 2 (d) shows an illustrative view of a train of unipolar voltage pulses with frequency f5 and amplitude V5 applied to the tunable PFN, and an output resonance asymmetrical AC voltage waveform from the tunable PFN in the resonance mode.

FIG. 2 (e) shows an illustrative circuit diagram of the tunable PFN when the plurality of inductors and capacitors are connected in series;

FIG. 2 (f) shows an illustrative circuit diagram of the tunable PFN when inductors and capacitors are connected in parallel;

FIG. 3 (a) shows an illustrative view of a train of input unipolar negative voltage pulses with two different voltage amplitudes applied to the tunable PFN.

FIG. 3 (b) shows an illustrative view of output resonance asymmetrical AC voltage waveform pulses with two different voltage amplitudes generated at resonance conditions in the tunable PFN;

FIG. 4(a) shows an illustrative circuit diagram of the tunable PFN and a plurality of electrical switches;

FIG. 4 (b) shows a train of resonance asymmetrical AC waveforms applied to different magnetically enhanced sputtering sources;

FIG. 5 (a) shows an illustrative view of the magnetically enhanced HEDP sputtering apparatus;

FIG. 5 (b) shows different voltage pulse shapes that can be generated by a substrate bias power supply;

FIG. 5 (c) shows an illustrative view of a via in the semiconductor wafer;

FIG. 6 (a) shows a train of resonance asymmetrical AC voltage waveforms;

FIG. 6 (b) shows a plurality of unipolar voltage pulses generated by a pulse DC power supply;

FIG. 6 (c) shows a plurality of unipolar RF voltage pulses generated by a pulse RF power supply;

FIG. 7 shows a block diagram of at least a portion of an exemplary machine in the form of a computing system that performs methods according to one or more embodiments disclosed herein;

FIG. 8 (a) shows an illustrative circuit diagram of a high-power pulse resonance AC power supply with an additional high-frequency power supply;

FIGS. 8 (b, c, d) show illustrative views of trains of oscillatory unipolar voltage pulses applied to the tunable PFN, and an output voltage waveform from the tunable PFN without a resonance mode in the tunable PFN;

FIGS. 9 (a, b) show a hollow cathode target combined from two pieces;

FIG. 10 (a) shows a hollow cathode target combined from two pieces and connected to two different power supplies;

FIG. 10 (b) shows the voltage output from two high-power pulse resonance AC power supplies;

FIG. 11 shows an illustrative circuit diagram of the high-power pulse resonance AC power supply that includes a pulse forming network having a transformer and diodes;

FIGS. 12 (a)-(g) show different AC voltage waveforms;

FIG. 13 shows arc resonance AC discharge current and arc resonance AC discharge voltage waveforms; and

FIGS. 14 (a, b) show output voltage waveforms from the high-power pulse resonance AC power supply when connected to the HEDP magnetron and generating HEDP discharge.

It is to be appreciated that elements in the figures are illustrated for simplicity and clarity. Common but well-understood elements that are useful or necessary in a commercially feasible embodiment are not shown in order to facilitate a less hindered view of the illustrated embodiments.

### DETAILED DESCRIPTION

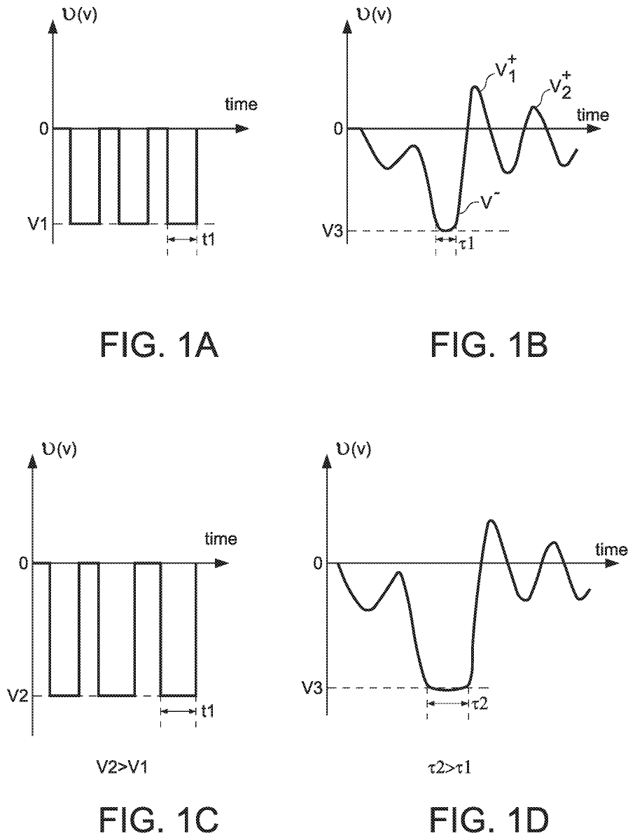

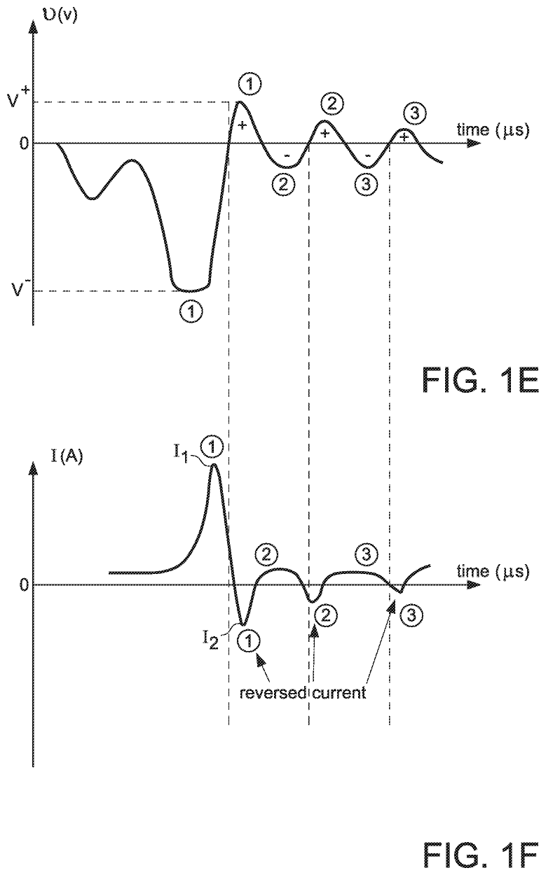

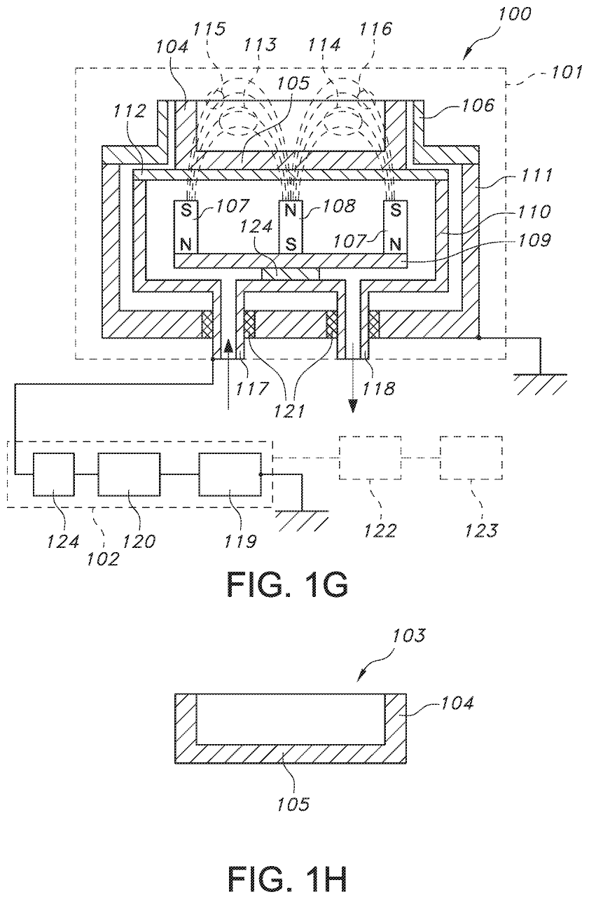

A high energy density plasma (HEDP) magnetically enhanced sputtering source includes a hollow cathode magnetron, pulse power supply, and tunable pulse forming network (PFN). The tunable PFN, in resonance mode, generates a high voltage asymmetrical alternating current (AC) waveform with a frequency in the range of 400 Hz to 400 kHz. The resonance mode of the tunable PFN, as used herein, is a mode in which input negative unipolar voltage pulses with adjusted amplitude, and programmed duration, and frequency generate an output high-power resonance pulse asymmetric AC voltage waveform with negative amplitude that exceeds or is equal to the negative amplitude of the input negative unipolar voltage pulses. Further increase of the amplitude of the input negative unipolar voltage pulses from the high-power pulse power supply does not increases the negative amplitude of the output high resonance asymmetric AC voltage waveform, but increases the duration of the maximum value of the negative resonance AC voltage waveform as shown in FIGS. 1 (a, b, c, d). In some embodiments a further increase of the amplitude of the input negative unipolar voltage pulses from the high-power pulse power supply increases the negative amplitude of the output high resonance asymmetric AC voltage waveform. When the amplitude of the input unipolar negative voltage pulses equals V1 as shown in FIG. 1 (a) at the output of the tunable PFN during the HEDP discharge, there is an asymmetrical resonance AC voltage waveform as shown in FIG. 1 (b). The resonance asymmetrical AC voltage waveform has a negative portion V⁺ with a duration τ1, and positive portions V₁⁺ and V₂⁺. When the amplitude voltage becomes V₂ and V₂>V₁, the amplitude of the resonance negative AC voltage waveform is the same as V₃, but the duration is τ2 and τ2>τ1. A negative portion of the resonance asymmetrical AC voltage waveform generates AC discharge current I₁ and positive voltage generates discharge current I₂ as shown in FIGS. 1 (e, f). A negative portion of the high-power asymmetrical resonance AC voltage waveform generates HEDP magnetron discharge from feed gas and sputtering target material atoms inside a hollow cathode target due to high discharge voltage and improved electron confinement. During the sputtering process, the hollow cathode target power density is in the range of 0.1 to 20 kW/cm². A positive portion of the high voltage asymmetrical AC voltage waveform provides absorption of electrons from the HEDP by the hollow cathode magnetron surface and, therefore, generates a positive plasma potential that causes ions to accelerate towards the hollow cathode target walls and a substrate. The ion energy is a function of the amplitude and duration of the positive voltage. The duration of the maximum absolute value of the negative voltage from the high voltage asymmetrical AC voltage waveform is in the range of 0.001-to 100 ms. The discharge current during the positive voltage of the asymmetrical resonance AC voltage waveform can be in the range of 5-50% of the discharge current during the negative voltage from the AC voltage waveform.

The high-power pulse resonance asymmetric AC HEDP magnetron sputtering process is substantially different from high-power impulse magnetron sputtering (HIPIMS) due to the resonance AC nature of the discharge generated by the tunable PFN and HEDP magnetron discharge. The resonance asymmetrical high-power AC discharge is substantially more stable when compared with HIPIMS discharge. In the resonance mode, the high-power AC voltage waveform can be symmetrical or asymmetrical. For example, for a carbon hollow cathode magnetron, a sputtering process with stable AC discharge current density of about 6 A/cm² is obtained. The disclosed embodiments relate to ionized physical vapor deposition (I-PVD) with an HEDP sputtering apparatus and method.

A sputtering process can be performed with a hollow cathode magnetron sputtering source and direct current (DC) power supply. An example of such an apparatus and sputtering process is described in Zhehui Wang and Samuel A. Cohen, Hollow cathode magnetron, J. Vac. Sci. Technol., Vol. 17, January/February 1999, which is incorporated herein by reference in its entirety. However, these techniques do not address operation of a hollow cathode magnetron sputtering source with a high voltage resonance asymmetrical AC voltage waveform, a method of accelerating ions from the feed gas and sputtering target material atoms by controlling a positive voltage portion of a high-power asymmetrical resonance AC voltage waveform applied to an entirely hollow cathode magnetron, or operation of a pulse power supply and tunable PFN when the tunable PFN is in a resonant mode and generating a high-power resonance asymmetrical AC voltage waveform on a hollow cathode magnetron sputtering source.

A magnetically and electrically enhanced HEDP sputtering source 100 shown in FIG. 1(g) includes a hollow cathode magnetron 101 and a high-power pulse resonance AC power supply 102, which includes a high-power voltage source 119, a high-power pulsed power supply with programmable voltage pulse frequency and amplitude 120, and tunable PFN 124. This tunable PFN, in resonance mode, generates a high-power resonance asymmetrical AC waveform. The hollow cathode magnetron 101 includes a hollow cathode target 103. The hollow cathode target 103 has side walls 104 and a bottom part 105 as shown in FIGS. 1 (g), (h). An anode 106 is positioned around the side walls 104. Magnets 107, 108, and magnetic pole piece 109 are positioned inside a water jacket 110. The water jacket 110 is positioned inside a housing 111. The hollow cathode target 103 is bonded to a copper backing plate 112. Magnets 107, 108 and magnetic pole piece 109 generate magnetic field lines 113, 114 that terminate on the bottom part 105 and form a magnetron configuration. Magnetic pole piece 109 is positioned on a supporter 124. Magnetic field lines 115, 116 terminate on the side walls 104. Water jacket 110 has a water inlet 117 and a water outlet 118. The water inlet 117 and water outlet 118 are isolated from housing 111 by isolators 121. Water jacket 110 and, therefore, hollow cathode target 101 are connected to a high-power pulse resonance AC power supply 102. The following chemical elements, or a combination of any two or more of these elements, can be used as a cathode material: B, C, Al, Si, P, S, Ga, Ge, As, Se, In, Sn, Sb, Te, I, Tl, Pb, Bi, Sc, Ti, Cr, Mn, Fe, Co, Ni, Cu, Zn, Y, Zr, Nb, Mo, Tc, Ru, Rh, Pd, Ag, Cd, Lu, Hf, Ta, W, Re, Os, Ir, Pt, Au, La, Ce, Pr, Nd, Pm, Sm, Eu, Gd, Tb, Dy, Ho, Er, Tm, Yb, Be, Mg, Ca, Sr, and/or Ba. A combination of these chemical elements with the gases O₂, N₂, F, Cl, and/or H₂ can also be used as the cathode material.

The hollow cathode target magnetic array may have electromagnets rather than permanent magnets. In some embodiments, the electromagnets are positioned around the side walls 104 of the hollow cathode target. These side electromagnets can balance and unbalance the hollow cathode target magnetic array.

In some embodiments, the hollow cathode target, during the sputtering process, has a temperature between 20 C and 1000 C. A high target temperature in the range of 0.5-0.7 of the melting target temperature increases the deposition rate since the sputtering yield is a function of the temperature in this temperature range. In some embodiments, a portion of the target material atoms arriving on the substrate is evaporated from the target surface. In some embodiments, the sputtering yield is increased due to high target temperature.

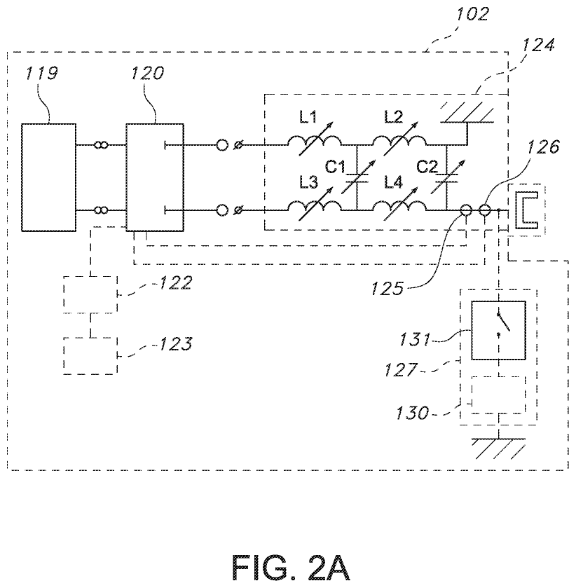

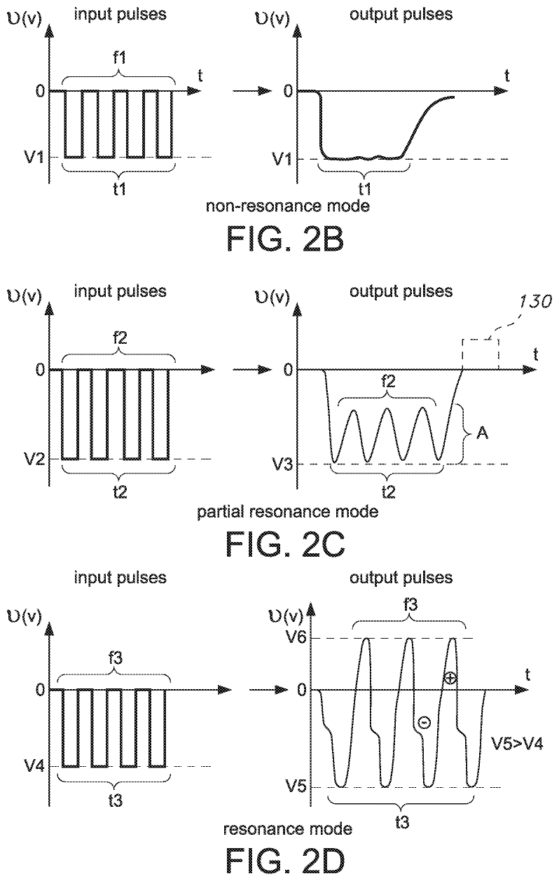

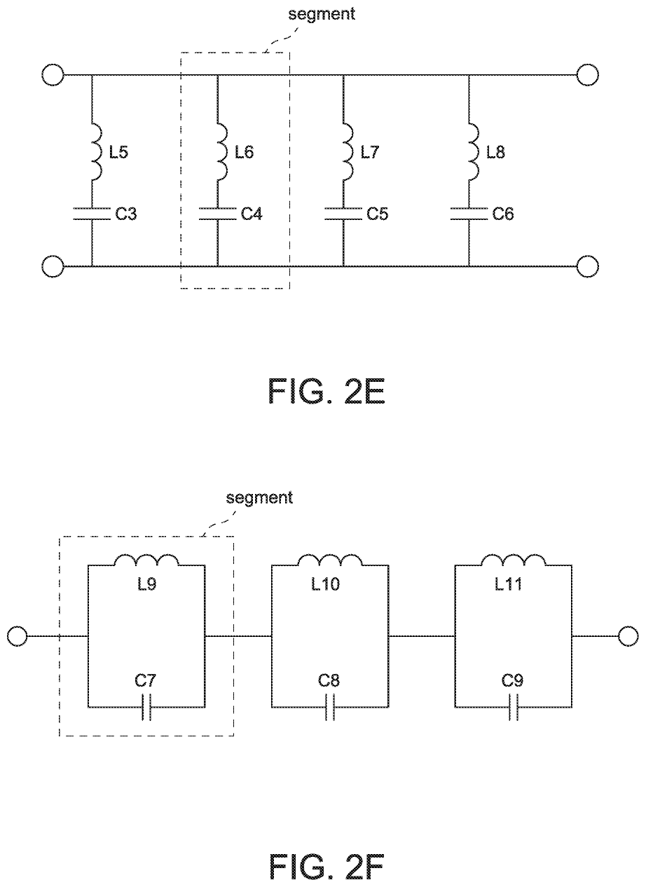

The high-power pulse resonance AC power supply 102 includes a regulated voltage source with variable power feeding 119, a high-power pulsed power supply with programmable voltage pulse frequency and amplitude 120 and tunable PFN 124 as shown in FIG. 2 (a). A high-power pulsed power supply with programmable voltage pulse frequency and amplitude 120 has a computer 123 and controller 122. A regulated voltage source with variable power feeding 119 supplies voltage in the range of 400-5000 V to the high-power pulsed power supply with programmable voltage pulse frequency and amplitude 120. The high-power pulsed power supply with programmable voltage pulse frequency and amplitude 120 generates a train of unipolar negative voltage pulses to the tunable PFN 124. The amplitude of the unipolar negative voltage pulses is in the range of 400 to 5000 V, the duration of each of the voltage pulses is in the range of 1 to 100 μs. The distance between voltages pulses can be in the range of 0.4 to 1000 μs, thus controlling the frequency to be between 0.1 to 400 kHz. In some embodiments, there is a step-up transformer between the high-power pulsed power supply with programmable voltage pulse frequency and amplitude 120 and the tunable PFN 124. In this case, the high-power pulsed power supply with programmable voltage pulse frequency and amplitude 120 generates a train of AC voltage waveforms coming to the step-up transformer. In some embodiments, there is a diode bridge between the step-up transformer and tunable PFN. The tunable PFN includes a plurality of specialized variable inductors L1-L4 and a plurality of specialized variable capacitors C1-C2 for high-power pulse applications. The value of the inductors and capacitors can be controlled by computer 123 and/or controller 122. In some embodiments, at least one inductor and/or one capacitor are variable and their values can be computer controlled. The inductors L1, L2, L3, L4 values can be in the range of 0 to 1000 μH each. Capacitors C1, C2, C3, and C4 have values in the range of 0 to 1000 μF each. The high-power pulse programmable power supply 120 is connected to controller 122 and/or computer 123. Controller 122 and/or computer 123 control output values and timing of the power supply 102. Power supply 102 can operate as a standalone unit without connection to the controller 122 and/or computer 123.

A high-power pulse resonance AC power supply 102 shown in FIG. 2(a) includes output current and voltage monitors 125, 126, respectively. The current and voltage monitors 125, 126 are connected to an arc suppression circuit 127. If the current monitor 125 detects a high current and the voltage monitor 126 detects a low voltage, the arc suppression circuit 127 is activated. It is to be noted that the voltage monitor 126 is connected to an output of the tunable PFN. The arc suppression circuit sends a signal to stop generating incoming voltage pulses to the tunable PFN 124 and connects the output of the tunable PFN through switch 131 to the positive electrical potential generated by power supply 130 in order to eliminate arcing as shown in FIG. 2 (a). The hollow cathode is shown as a C-shaped structure coupled to the output of the tunable PFN 124.

The train of unipolar negative voltage pulses from the high-power pulse programmable power supply 120 is provided to the tunable PFN 124. Depending on the amplitude, duration, and frequency of the input unipolar negative voltage pulses in the train, the output train from the tunable PFN 124 of the unipolar negative voltage pulses can have a different shape and amplitude when compared with input unipolar negative voltage pulses. In non-resonant mode, in the tunable PFN 124, the input train of negative unipolar pulses forms one negative voltage pulse with an amplitude equivalent to the amplitude of the negative unipolar voltage pulses and a duration equivalent to the duration of the input train of unipolar negative voltage pulses. When connected with the magnetically enhanced sputtering source, this voltage pulse can generate a quasi-static pulse DC discharge. In partial resonance mode, in the tunable PFN 124, the input train of negative unipolar pulses forms one negative pulse with an amplitude and duration, but with voltage oscillations. The amplitude of these oscillations can be 30-80% of the total voltage amplitude. The frequency of the voltage oscillations is substantially equivalent to the frequency of the input unipolar negative voltage pulses. This mode of operation is beneficial to maintaining a high deposition rate, which is greater than that obtained in full resonance mode, and a high ionization of sputtered target material atoms. In resonance mode, the input train of unipolar negative voltage pulses forms asymmetrical AC voltage waveforms with a maximum negative voltage amplitude that can significantly exceed the voltage amplitude of the input unipolar negative voltage pulses. In some embodiments, in resonance mode, the input train of unipolar negative voltage pulses forms asymmetrical AC voltage waveforms with a maximum negative voltage amplitude that does not exceed the voltage amplitude of the input unipolar negative voltage pulses. The positive amplitude of the AC voltage waveform can reach the absolute value of the negative amplitude and form a symmetrical AC voltage waveform. In FIG. 2 (b), the pulsing unit generates, during time t1, a train of unipolar negative voltage pulses with a frequency f1 and amplitude V1.

In FIG. 2 (c), the high-power pulse programmable power supply 119 generates, during time t2, a train of unipolar negative voltage pulses with a frequency f2 and amplitude V2. In this case, the partial resonance mode exists. The amplitude A of the voltage oscillations is about 30-80% of the voltage amplitude V2. At the end of the pulse, the positive voltage pulse 130 can be added by activating a positive voltage power supply connected to the output of the tunable PFN. If the high-power pulse programmable power supply 120 generates unipolar voltage pulses with a frequency f3 and amplitude V4 during time t3, the resonance mode exists in the PFN 124. The resonance mode generates asymmetrical AC voltage waveform. The negative voltage amplitude V5 exceeds the amplitude of the input voltage pulses V4 as shown in FIG. 2 (d). In some embodiments, the amplitude of the voltage pulses V4 is −1200 V, amplitude of the negative voltage V5 is −1720 V. and the amplitude of the positive voltage V6 is +280 V. In some embodiments, the amplitude of the voltage pulses V4 is −1500 V, and amplitude of the negative voltage V5 is −1720 V. The amplitude of the output positive voltage V6 is +780 V. Different tunable PFN that can be used to generate asymmetrical AC voltage waveforms are shown in FIGS. 2 (e, f).

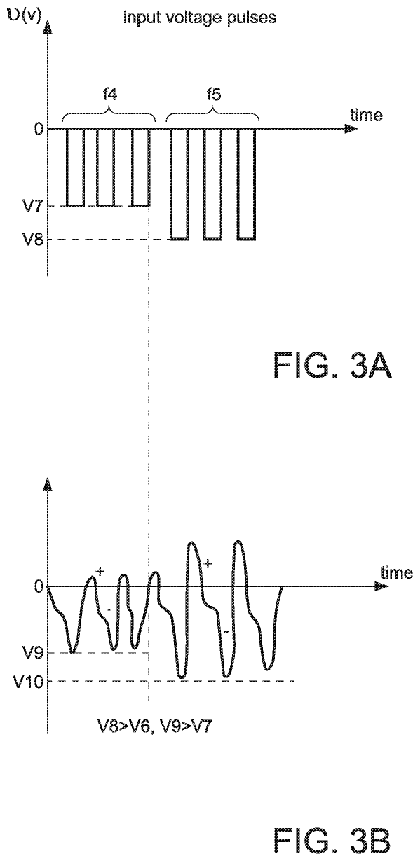

In some embodiments, the high-power pulse programmable power supply pulsing 120 can generate a train of unipolar negative voltage pulses with different amplitudes V7, V8 and frequencies f4, f5 as shown in FIG. 3 (a). There is a resonance mode in the tunable PFN 124 when the output negative voltage amplitudes V9, V10 exceed the amplitude of the input voltage pulses V7, V8 as shown in FIG. 3 (b). During a negative portion of the asymmetrical AC discharge, a surface of the hollow cathode target 103 emits secondary electrons due to ion bombardment, and during the positive portion of the asymmetrical AC discharge the hollow cathode 103 absorbs electrons. The reduced amount of electrons in the plasma generates a positive plasma potential. This plasma potential accelerates ions towards the substrate.

During a reactive sputtering process, positive electrical charge is formed on the hollow cathode target surface 107 due to reactive feed gas interaction with the hollow cathode target surface 107. The positive voltage of the asymmetrical high voltage AC waveform attracts electrons to the hollow cathode target surface. These electrons discharge a positive charge on top of the cathode target surface 107 and significantly reduce or completely eliminate the probability of arcing. Since the electrons are absorbed by the hollow cathode target surface 107, it is possible to generate positive space charge in the plasma. The positive space charge provides additional energy to the ions in the plasma and leads the ions toward the substrate and hollow cathode target walls. The positive voltage applied to the cathode target surface can attract negative ions that were formed when the negative voltage was applied to the target surface and, therefore, reduce substrate ion bombardment.

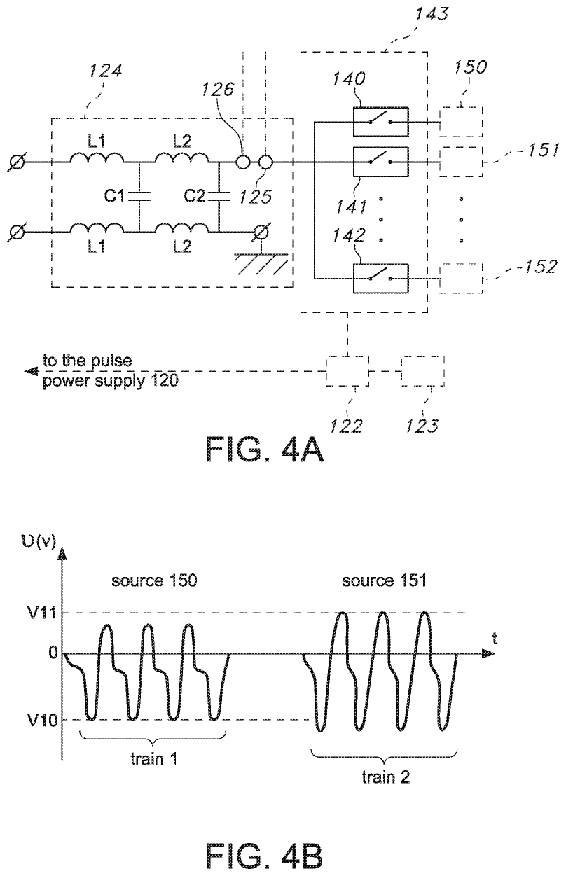

The tunable PFN 124 can be connected with a plurality of electrical switches 140-142. The switches 140, 141, 142 are connected to separate magnetron sputtering sources 150, 151, 152 as shown in FIG. 4 (a). For example, during operation, the train 1 of pulses of high voltage AC waveform is directed to the sputtering source 150, and the train 2 of pulses of high voltage AC waveform is directed to the sputtering source 151 as shown in FIG. 4 (b). In this approach, small size sputtering sources can provide large area sputtering.

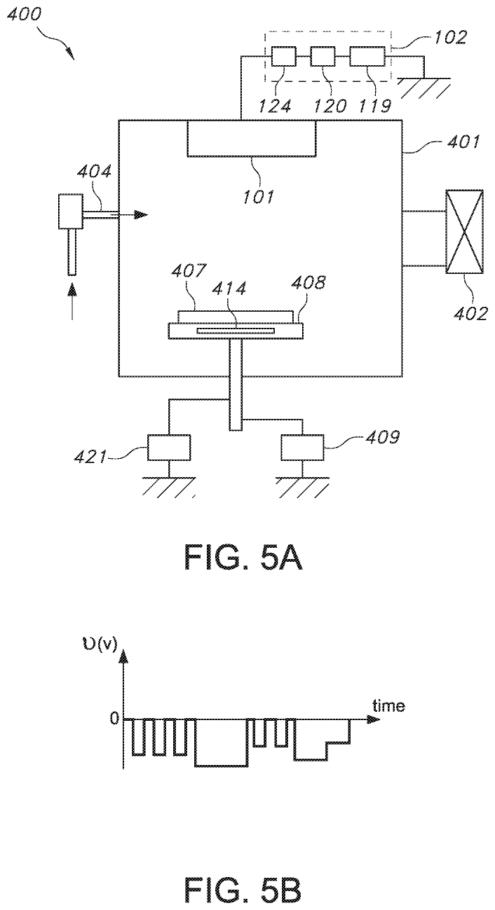

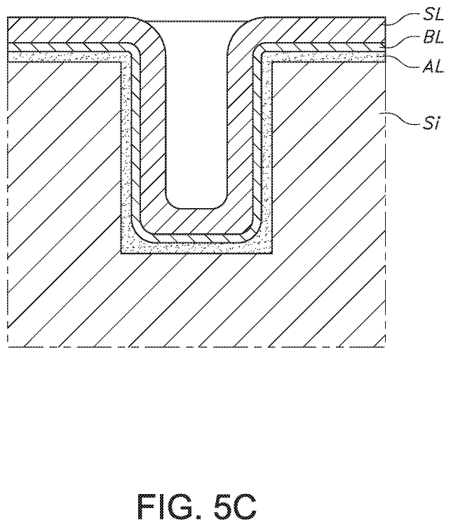

The hollow cathode magnetron 101 from the magnetically and electrically enhanced HEDP sputtering source 100 is mounted inside a vacuum chamber 401 to construct the magnetically and electrically enhanced HEDP sputtering apparatus 400 shown in FIG. 5 (a). The vacuum chamber 401 contains feed gas and plasma, and is coupled to ground. The vacuum chamber 401 is positioned in fluid communication with a vacuum pump 402, which can evacuate the feed gas from the vacuum chamber 401. Typical baseline pressure in the vacuum chamber 401 is in a range of 10⁻⁶ to 10⁻⁹ Torr.

A feed gas is introduced into the vacuum chamber 401 through a gas inlet 404 from feed gas sources. A mass flow controller 404 controls gas flow to the vacuum chamber 401. In an embodiment, the vacuum chamber 401 has a plurality of gas inlets and mass flow controllers. The gas flow is in a range of 1 to 1000 SCCM depending on plasma operating conditions, pumping speed of a vacuum pump 403, process conditions, and the like. Typical gas pressure in the vacuum chamber 401 during a sputtering process is in a range of 0.5 to 50 mTorr. In some embodiments, a plurality of gas inlets and a plurality of mass flow controllers sustain a desired gas pressure during the sputtering process. The plurality of gas inlets and plurality of mass flow controllers may be positioned in the vacuum chamber 401 at different locations. The feed gas can be a noble gas, such as Ar, Ne, Kr, Xe; a reactive gas, such as N₂, O₂; or any other gas suitable for sputtering or reactive sputtering processes. The feed gas can also be a mixture of noble and reactive gases.

The magnetically enhanced HEDP sputtering apparatus 400 includes a substrate support 408 that holds a substrate 407 or other work piece for plasma processing. The substrate support 408 is electrically connected to a bias voltage power supply 409. The bias voltage power supply 409 can include a radio frequency (RF) power supply, alternating current (AC) power supply, very high frequency (VHF) power supply, and/or direct current (DC) power supply. The bias power supply 409 can operate in continuous mode or pulsed mode. The bias power supply 409 can be a combination of different power supplies that can provide different frequencies. The negative bias voltage on the substrate is in a range of 0 to −2000 V. In some embodiments, the bias power supply generates a pulse bias with different voltage pulse frequency, amplitude, and shape as shown in FIG. 4 (b). In some embodiments, the voltage is a pulse voltage. The negative substrate bias voltage can attract positive ions to the substrate. The substrate support 408 can include a heater 414 that is connected to a temperature controller 421. The temperature controller 421 regulates the temperature of the substrate 407. In an embodiment, the temperature controller 420 controls the temperature of the substrate 407 to be in a range of −100 C to (+1000) C.

In some embodiments, the hollow cathode target material is copper and the substrate is a semiconductor wafer that has at least one via or trench. The semiconductor wafer diameter is in the range of 25 to 450 mm. The depth of the via can be between 100 Å and 400 μm. The via can have an adhesion layer, barrier layer, and seed layer. Typically, the seed layer is a copper layer. The copper layer can be sputtered with the HEDP magnetron discharge as shown in FIG. 5 (c).

A method of sputtering films, such as hard carbon, includes the following conditions. The feed gas pressure can be in the range of 0.5 to 50 mTorr. The substrate bias can be between 0 V and −120 V. The substrate bias voltage can be continuous or pulsed. The frequency of the pulsed bias can be in the range of 1 Hz and 400 kHz. The substrate bias can be generated by RF power supply and matching network. The RF frequency can be in the range of 500 kHz and 27 MHz. The RF bias can be continuous or pulsed. In embodiment during the deposition the substrate can have a floating potential. The high-power pulse power supply 120 generates a train of negative unipolar voltage pulses with frequency and amplitude that provide a resonance mode in the tunable PFN 124. In this case, tunable PFN 124 generates the high voltage asymmetrical AC waveform and, therefore, generates HEDP discharge. The negative AC voltage can be in the range of −1000 to −10000 V. The duration of the pulse high voltage asymmetrical AC waveforms can be in the range of 1 to 20 msec. The substrate temperature during the sputtering process can be in the range of −100 C and +200 C. The hardness of the diamond like coating formed on the substrate can be in the range of 5 to 70 GPa. The concentration of sp3 bonds in the carbon film can be in the range of 10-80%. In some embodiments, the concentration of sp2 bonds in the carbon film can be in the range of 80 and 100%. In some embodiments, the feed gas is a noble gas such as Ar, He, Ne, and Kr. In some embodiments, the feed gas is a mixture of a noble gas and hydrogen. In some embodiments, the feed gas is a mixture of a noble gas and a gas that contains carbon atoms. In some embodiments, the feed gas is a mixture of a noble gas and oxygen in order to sputter oxygenated carbon films COₓ for non-volatile memory devices or any other devices. The oxygen gas flow can be in the range of 1-100 sccm. The discharge current density during the sputtering process can be 0.2-20 A/cm². In some embodiments, the amorphous carbon films are sputtered for non-volatile memory semiconductor based devices or for any other semiconductor based devices.

In some embodiments, the hollow cathode target material is aluminum. The feed gas can also be a mixture of argon and oxygen, or argon and nitrogen. The feed gases pass through a gas activation source. In some embodiments, feed gasses pass directly to the vacuum chamber. PFN 124 generates the asymmetrical high voltage AC waveform to provide HEDP magnetron discharge to sputter hard α-Al₂O₃ or γ-Al₂O₃ coating on the substrate. The substrate temperature during the sputtering process is in the range of 350 to 800 C.

HEDP magnetron discharge can be used for sputter etching the substrate with ions from sputtering target material atoms and gas atoms. A method of sputter etch processing with argon ions and sputtered target material ions uses high negative substrate bias voltage in the range of −900 to −1200 V. The gas pressure can be in the range of 1 to 50 mTorr. The pulse power supply generates a train of negative unipolar voltage pulses with frequency and amplitude that provide resonance mode in the tunable PFN 124. In this case, the PFN 124 generates the high voltage asymmetrical AC voltage waveform that provides HEDP discharge. For example, a sputter etch process can be used to sharpen or form an edge on a substrate for cutting applications, such as surgical tools, knives, inserts for cutting tools or razor blade for hair removal applications, or for cleaning a substrate by removing impurities to enhance adhesion. HEDP magnetron discharge also can be used for ion implantation of ions from sputtered target material atoms into a substrate. For ion implantation, the negative bias voltage on the substrate can be in the range −900-15000 V. An ion implantation example includes the doping of a silicon based device or ion implantation to enhance thin film adhesion to the substrate where the layer is forming.

In some embodiments, the electrically enhanced HEDP magnetron sputtering source can be used for chemically enhanced I-PVD deposition (CE-IPVD) of metal containing or non-metal films. For example, in order to sputter carbon films with different concentrations of sp3 bonds in the film, the cathode target may be made from carbon material. The feed gas can be a noble gas and carbon atoms containing gas, such as C₂H₂, CH₄, or any other gases. The feed gas can also contain H₂. Carbon films on the substrate are formed by carbon atoms from the feed gas and from carbon atoms from the cathode target. The carbon films on the substrate are formed by carbon atoms from the feed gas.

The carbon films sputtered with the electrically enhanced HEDP magnetron sputtering source with noble gas, such as Argon, Neon, Helium and the like, or reactive gas, such as Hydrogen, Nitrogen, Oxygen, and the like can be used for hard mask applications in etch processes, such as 3D NAND; for protectively coating parts, such as bearings, camshafts, gears, fuel injectors, cutting tools, inserts for cutting tools, carbide inserts, drill bits, broaches, reamers, razor blades for surgical applications and hair removal, hard drives, solar panels, optical filters, flat panel displays, thin film batteries, batteries for storage, hydrogen fuel cell, cutleries, jewelry, wrist watch cases and parts, coating metal on plastic parts such as lamps, air vents in cars, aerospace applications, such as turbine blades and jet engine parts, jewelry, plumbing parts, pipes, and tubes; medical implants, such as stents, joints, cell phone, mobile phone, iPhone, iPod, touch screen, hand held computing devices, application specific integration circuits and the like.

The carbon films sputtered with the electrically enhanced HEDP magnetron sputtering source can be used to sputter thin ta-C and COₓ films for carbon based resistive memory devices.

In some embodiments, the HEDP magnetron discharge with a carbon target is used to grow carbon nanotubes. In some embodiments, these nanotubes are used to build memory devices.

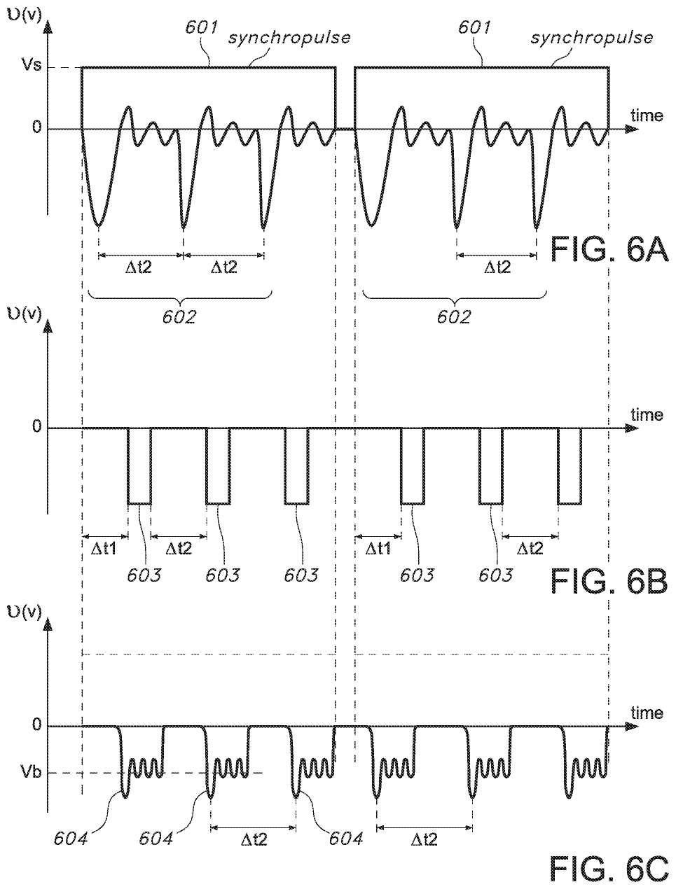

During the HEDP sputtering process, when the high-power pulse asymmetric AC voltage waveform is applied to the magnetically enhanced sputtering source, a pulse bias voltage can be applied to the substrate to control ion bombardment of the growing film. In some embodiments, during the HEDP sputtering process, when the high-power pulse asymmetric AC voltage waveform is applied to the magnetically enhanced sputtering source, a pulse bias voltage can be applied to the substrate to control ion bombardment of the growing film. The amplitude of the negative voltage can be in the range of −10 V and −200 V. Trains of asymmetrical AC voltage waveforms 602 are shown in FIG. 6 (a). Trains of negative voltage pulses 603 applied to the substrate are shown in FIG. 6 (b). In order to control time t1 when bias voltage pulse is applied to the substrate, the high-power pulse resonance AC power supply and bias power supply are synchronized. In this case, the controller from the high-power pulse resonance AC power supply sends synchronization pulses that correspond to the trains of asymmetrical AC voltage waveforms to the controller from the bias power supply. The bias power supply controller can set time Δt1 in the range of 0-1000 μs.

In some embodiments, the bias power supply includes an RF power supply. FIG. 6 (c) shows a train of RF pulses 604 generated by the RF bias power supply.

The method of generating resonance AC voltage waveforms for the magnetically enhanced sputtering source can also be used to generate resonance AC waveforms for the cathodic arc evaporation sources that have widespread applications in the coating industry. Resonance AC voltage wave waveforms, when connected with a magnetically enhanced sputtering source, generate volume discharge. Resonance AC voltage waveforms, when connected with an arc evaporation source, generate point arc discharge. DC power supplies generate and sustain continuous arc discharge on an arc evaporation source with a carbon target. The arc current can be in the range of 40-100 A. The arc discharge voltage can be in the range of 20-120 V. A regulated voltage with a variable power source feeds the high-power pulse programmable power supply. Specifically, the high-power pulse asymmetric AC voltage waveform is generated by having the regulated voltage source with variable power feeding a regulated voltage to the high-power pulse supply with programmable pulse voltage duration and pulse voltage frequency producing at its output a train of regulated amplitude unipolar negative voltage pulses with programmed pulse frequency and duration, and supplying these pulses to a tunable pulse forming network (PFN) including a plurality of specialized inductors and capacitors designed for pulse applications connected in a specific configuration coupled to an arc evaporation source. The resonance occurs in the PFN and in the already existing arc discharge generated by the DC power supply. By adjusting the pulse voltage amplitude, duration, and frequency of the unipolar negative voltage pulses and tuning the values of the inductors and capacitors in the PFN coupled to an arc evaporation source, a resonance pulsed asymmetric AC arc discharge can be achieved.

Another method of producing a resonance pulsed asymmetric AC arc discharge is to have fixed unipolar pulse power supply parameters (amplitude, frequency, and duration) feeding a pulsed forming network, in which the numerical values of the inductors and capacitors, as well as their configurations are tuned to achieve the desired resonance values on the arc evaporation source to form a layer on the substrate. The tuning of the PFN can be performed manually with test equipment, such as an oscilloscope, voltmeter, and current meter or other analytical equipment; or electronically with a built-in software algorithm, variable inductors, variable capacitors, and data acquisition circuitry. The negative voltage from the pulse asymmetric AC voltage waveform generates high density plasma from the evaporated target material atoms between the cathode target and the anode of the arc evaporation source. The positive voltage from the pulse asymmetrical AC voltage waveform attracts plasma electrons to the cathode area and generates positive plasma potential. The positive plasma potential accelerates evaporated target material ions from the cathode target area towards the substrate that improve deposition rate and ion bombardment on the substrate. The reverse electron current can be up to 50% from the discharge current during the negative voltage. In some embodiments, the arc evaporation source may have one of a rotatable magnetic field, movable magnetic field, or stationary magnetic field. The tunable PFN includes a plurality of capacitors and inductors. The resonance mode associated with the tunable PFN is a function of the input unipolar voltage pulse amplitude, duration, and frequency generated by the high-power pulse power supply; inductance, resistance, and capacitance of the arc evaporation source, or any other magnetically enhanced arc evaporation source; the inductance, capacitance, and resistance of the cables between the tunable PFN and arc evaporation source; and a plasma impedance of the arc evaporation source itself as well as the evaporated material. In the resonance mode, the output negative voltage amplitude of the high-power pulse voltage mode asymmetrical AC waveform on the arc evaporation source exceeds the negative voltage amplitude of the input unipolar voltage pulses into the tunable PFN by 1.1-5 times. The unipolar negative high-power voltage output can be in the range of 400V-5000V. In the resonance mode, the absolute value of the negative voltage amplitude of the asymmetrical AC waveform can be in the range of 750-5000 V. In the resonance mode, the output positive voltage amplitude of the asymmetrical AC waveform can be in the range of 100-2500 V.

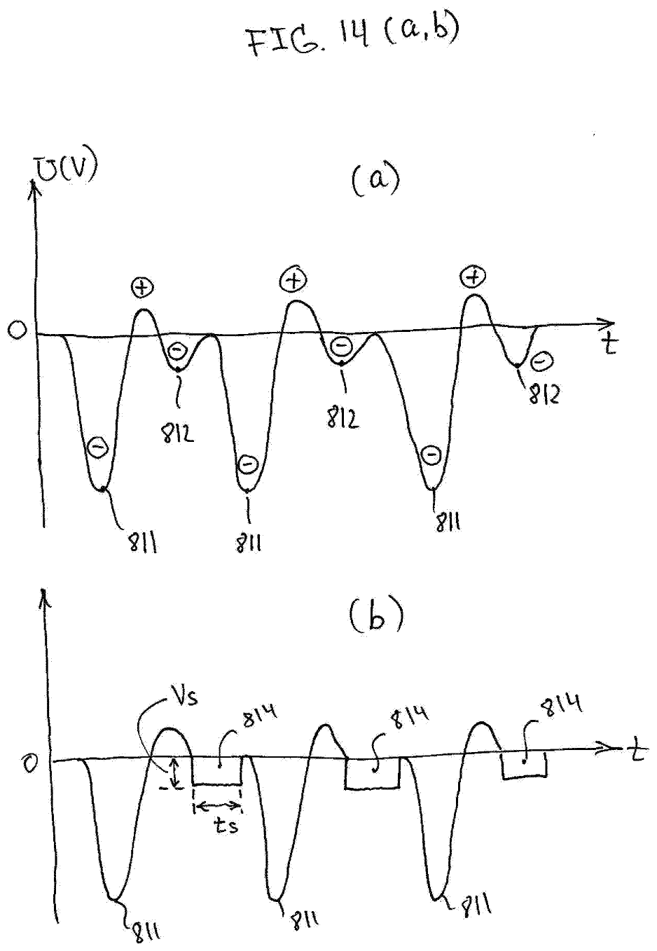

In the resonance mode, the negative voltage amplitude of the output AC waveform can reach a maximum absolute value at which point a further increase of the input voltage to the tunable PFN will not result in a voltage amplitude increase, but rather an increase in duration of the negative pulse in the asymmetric AC waveform. In some embodiments, in the resonance mode, the negative voltage amplitude of the output AC waveform can reach a maximum absolute value, at which point a further increase of the input voltage to the tunable PFN will result in a positive voltage amplitude increase. In some embodiments, the frequency of the unipolar voltage pulses is in the range of 1 kHz and 10 kHz. In some embodiments, the duration of the unipolar voltage pulses is in the range of 3-20 μs. Asymmetrical AC voltage waveforms significantly influence the size on of the cathode arc spot and velocity. In some embodiments, generation of the resonance AC voltage waveforms reduce the formation of macro particles from evaporated cathode target material. The arc discharge current during the negative portion of the AC voltage can be in the range of 200-3000 A. The arc discharge current during the positive portion of the AC voltage has a lower value and can be in the range of 10-500 A. The arc AC discharge current and arc discharge AC voltage waveforms are shown in FIG. 13.

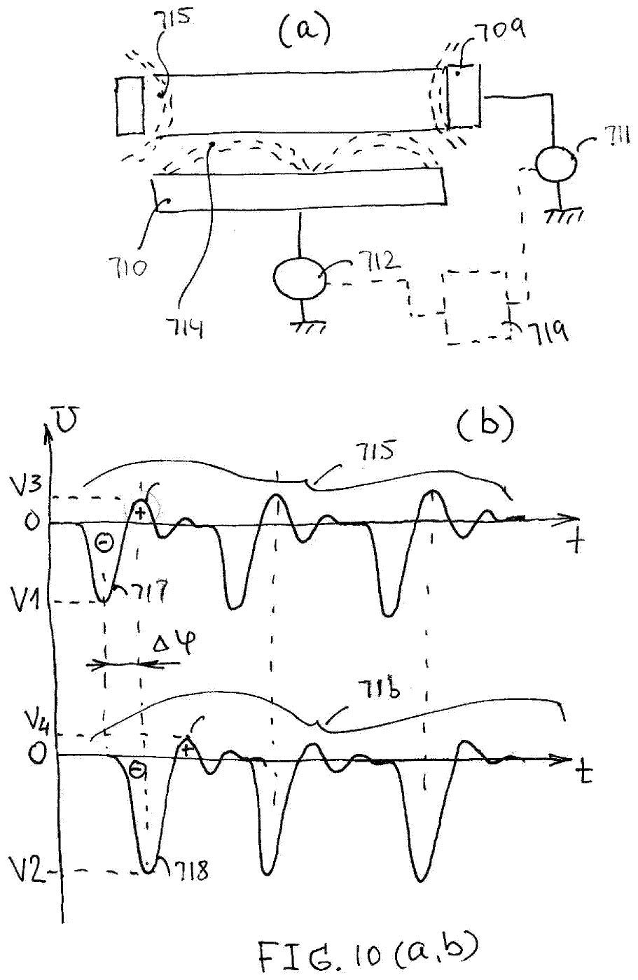

In an embodiment, a high-power pulse resonance AC power supply 700, as compared with the high-power pulse resonance AC power supply 102 shown in FIG. 1(g), includes a high frequency high-power pulsed power supply 701 with a programmable voltage pulse frequency and amplitude as shown in FIG. 8 (a). The high frequency high-power pulsed power supply 701 generates pulse negative, unipolar oscillatory voltage waveforms with a frequency in the range of 100 KHz to 5 MHz and a duration t1 in a range of 5 μs to 20 μs. The absolute value of the voltage of these waveforms is in a range of 500 V to 5000 V. The frequency of these pulses with negative unipolar voltage waveforms is in a range of 5 Hz to 200 KHz.

Pulse negative unipolar oscillatory voltage waveforms 800 are shown in FIG. 8 (b). The tunable PFN 124, which is in resonance mode for these pulses, generates a high-power resonance asymmetrical AC waveform. The resonance mode can be achieved by adjusting the values of inductors L1, L2, L3, and L4, and by adjusting the values of capacitors C1 and C2 for a particular shape of the pulse negative unipolar oscillatory voltage waveforms, their frequency, type of process gas, target material, and magnetic field strength of the hollow cathode sputtering source 702. The resonance mode is defined as the prevailing conditions when the adjustment of the frequency and amplitude of the plurality of negative unipolar oscillatory voltage waveforms 800 generate the plurality of asymmetrical AC voltage waveforms 801 with positive V+ and negative V− voltages shown in FIGS. 8 (b, c). Further increase of the oscillatory voltage waveform amplitude causes an increase in the value of the positive portion of the AC voltage waveform. By adjusting time t1, rt2, or both t1 and t2, double negative peak asymmetrical AC voltage waveforms 802 can be achieved as shown in FIG. 8 (d).

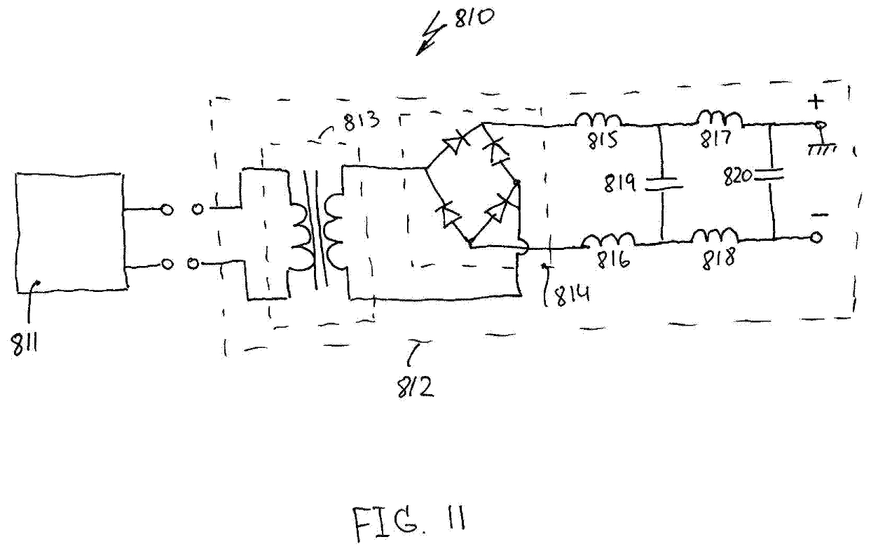

In an embodiment, a magnetically and electrically enhanced HEDP sputtering source 100 shown in FIG. 1(g) has a hollow cathode target 103 that includes two parts as shown in FIG. 9 (a) and FIG. 9 (b). FIG. 9 (a) shows the hollow cathode target 103 that includes pieces 703 and 705. These two pieces are attached to a copper baking plate by a clamp 704. FIG. 9 (b) shows the hollow cathode target that includes pieces 707 and 708. These two pieces are bonded to a copper baking plate 706. The magnetically and electrically enhanced HEDP sputtering source can have a diameter in the range of 1 cm to 100 cm. The peak power density can be in the range of 100 W/cm² to 20 kW/cm². The average power density can be in the range of 50 W/cm² to 150 W/cm².

In an embodiment, the hollow cathode target 103 includes two pieces 710 and 709 as shown in FIG. 10 (a). The piece 709 has magnetic field lines 715 and the piece 710 has magnetic field lines 714. Each of these pieces is connected to different high-power pulse resonance AC power supplies 711 and 712. The block diagram of these high-power pulse resonance AC power supplies is shown in FIG. 8 (a). The high-power pulse resonance AC power supplies 711 and 712 generate AC voltage waveforms 715 and 716 shown in FIGS. 10 (a) and 10 (b). A time shift between negative voltage peaks 717 and 718 is controlled by controller 719. In an embodiment, the power supply 711 sends a synchro pulse to power supply 712 to initiate the start of power supply 712. In an embodiment, the power supply 712 sends a synchro pulse to power supply 711 to initiate the start of power supply 711.

In an embodiment, a magnetically enhanced HEDP sputtering source that is shown in FIG. 1 (g) includes an additional magnetic assembly positioned adjacent to the side walls 104 as shown in FIG. 1 (h). The magnetic assembly may have permanent magnets, electromagnets, or a combination of permanent magnets and electromagnetics.

The method of generating resonance AC voltage waveforms for the magnetically enhanced sputtering source and high-power pulse resonance AC power supply 700 can also be used to generate resonance AC waveforms for cathodic arc evaporation sources. High-power pulse resonance AC power supply 700 can be used for all applications in which the high-power pulse resonance AC power supply 102 can be used.

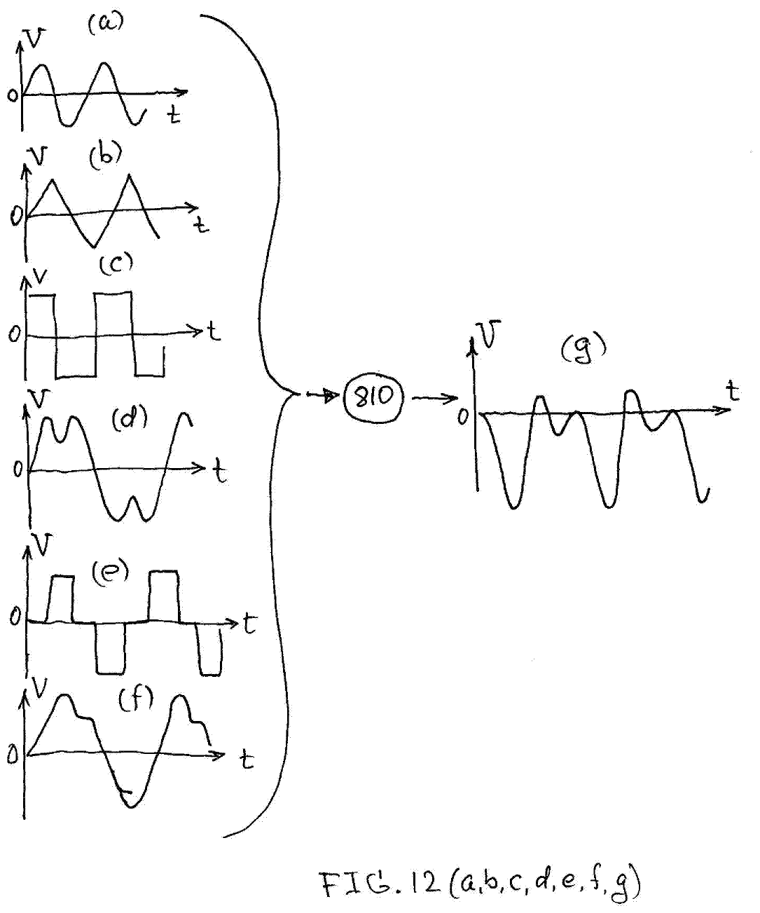

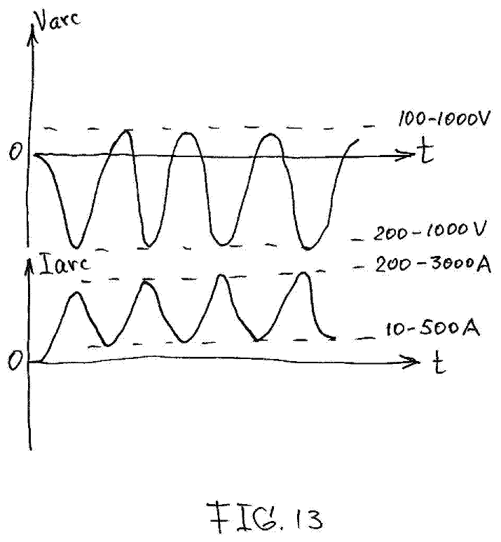

In an embodiment, a high-power pulse resonance AC power supply 810 includes an AC power supply 811 and PFN 812 as shown in FIG. 11. High-power AC power supply 811 can generate different AC voltage waveforms at the output as shown in FIGS. 12 (a, b, c, d, e, f). The frequency of these voltage waveforms can be in the range of 3 KHz to 100 KHz. The peak voltage amplitude can be in the range of 100 V to 1000 V. The PFN includes a step-up transformer 813, a diode bridge 814, a plurality of inductors 815, 816, 817, 818 and a plurality of capacitors 819 and 820. This PFN converts AC voltage waveforms to an asymmetrical complex AC voltage waveform during the resonance mode as shown in FIG. 11. AC voltage waveforms and frequencies that correspond to this particular AC voltage waveform are associated with specific values of inductors (815, 816, 817 and 818) and capacitors (819, 820) in order to generate the resonance mode and form, at the output, the asymmetrical AC voltage waveform. In an embodiment, the PFN does not have a diode bridge.

In an embodiment, the high-power pulse resonance AC power supply can be connected to the HEDP magnetron sputtering source and RF power supply simultaneously. The frequency of the RF power supply can be in the range of 500 KHz to 30 MHz. The RF power supply can operate in continuous mode or pulsed mode. In an embodiment, the RF power supply turns on before on the high-power pulse resonance AC power supply turns on (Roman, is this correct? YES) in order to provide stable plasma ignition for plasma that will be generated with the high-power pulse resonance AC power supply. The RF power supply can be turned off after the high-density plasma is generated. In an embodiment, the RF power supply operates in continuous mode together with the high-power pulse resonance AC power supply. This operation reduces parasitic arcs during the reactive sputtering process. This operation is beneficial for sputtering ceramic target materials and target materials with low electrical conductivity such as those containing B, Si, and the like.

The output voltage waveforms from the high-power pulse resonance AC power supply are shown in FIG. 14s (a, b). The second negative peak 812 can be generated by controlling parameters of the PFN, such as inductors, capacitors and the transformer (if applicable) as shown in FIG. 14 (a). The peak 812 has a significant influence on the probability of generating arcs during reactive sputtering. The plasma that is generated during this peak helps to ignite high density plasma during the first negative peak 811. The second peak 812 may be triangular, sinusoidal or rectangular in shape. The rectangular shape of the second negative peak 814 is shown in FIG. 14 (b). The value and duration of the peak 812 helps to control the energy of ions coming to the substrate. The duration tₛ can be in the range of 2 μs to 50 μs. The amplitude Vₛ can be in the range of 200 V to 1000 V. The greater the amplitude and/or duration of the second peak is, the less the ion energy will be. This arrangement is of particular importance for sputtering ta-C films when high ion energy can affect the structure of the growing film.

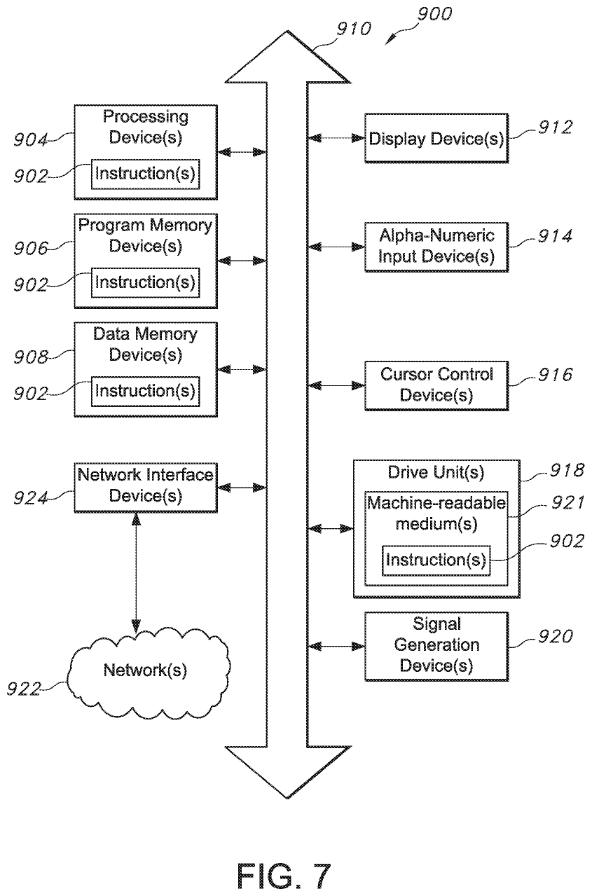

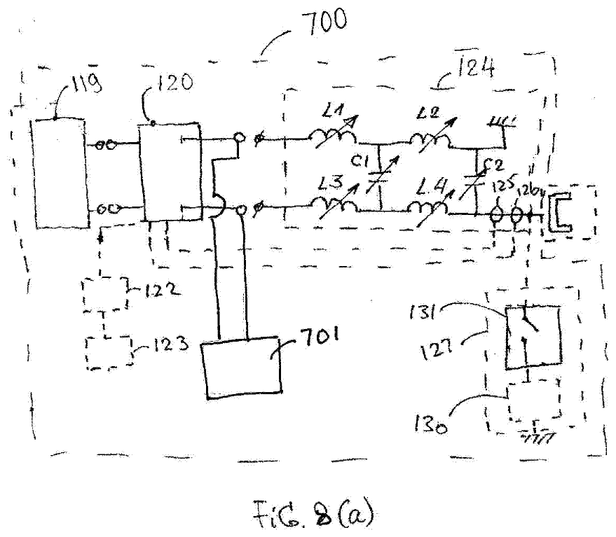

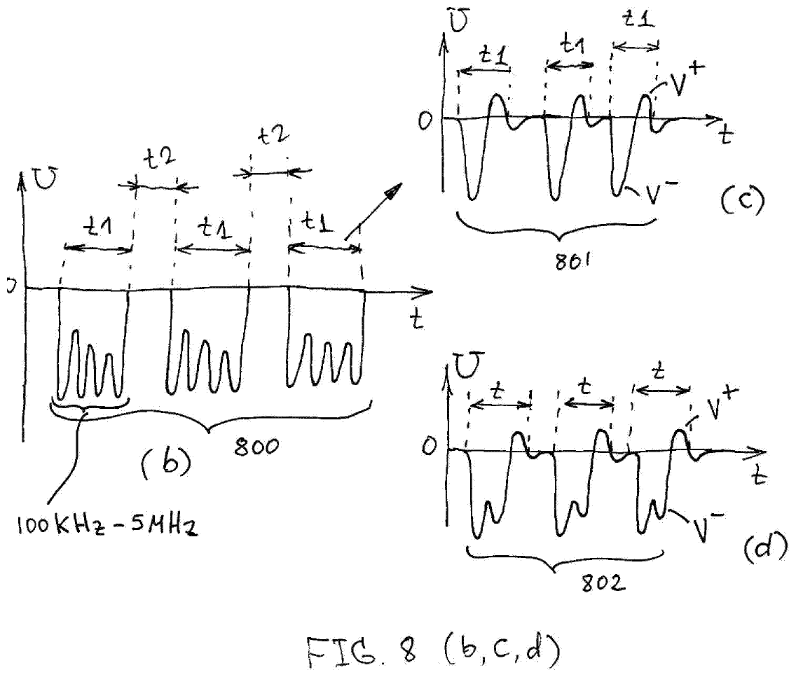

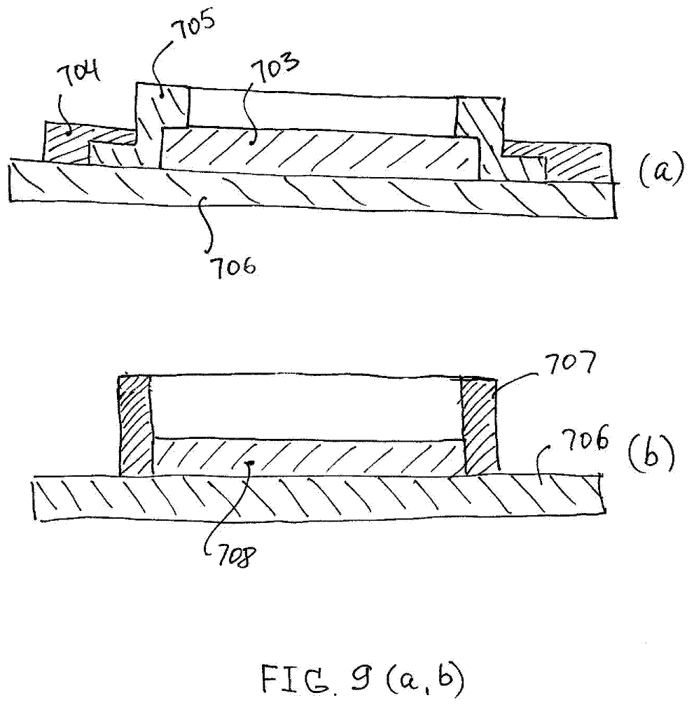

One or more embodiments disclosed herein, or a portion thereof, may make use of software running on a computer or workstation. By way of example, only and without limitation, FIG. 7 is a block diagram of an embodiment of a machine in the form of a computing system 900, within which is a set of instructions 902 that, when executed, cause the machine to perform any one or more of the methodologies according to embodiments of the invention. In one or more embodiments, the machine operates as a standalone device; in one or more other embodiments, the machine is connected (e.g., via a network 922) to other machines. In a networked implementation, the machine operates in the capacity of a server or a client user machine in a server-client user network environment. Exemplary implementations of the machine as contemplated by embodiments of the invention include, but are not limited to, a server computer, client user computer, personal computer (PC), tablet PC, personal digital assistant (PDA), cellular telephone, mobile device, palmtop computer, laptop computer, desktop computer, communication device, personal trusted device, web appliance, network router, switch or bridge, or any machine capable of executing a set of instructions (sequential or otherwise) that specify actions to be taken by that machine.

The computing system 900 includes a processing device(s) 904 (e.g., a central processing unit (CPU), a graphics processing unit (GPU), or both), program memory device(s) 906, and data memory device(s) 908, which communicate with each other via a bus 910. The computing system 900 further includes display device(s) 912 (e.g., liquid crystal display (LCD), flat panel, solid state display, or cathode ray tube (CRT)). The computing system 900 includes input device(s) 914 (e.g., a keyboard), cursor control device(s) 916 (e.g., a mouse), disk drive unit(s) 918, signal generation device(s) 920 (e.g., a speaker or remote control), and network interface device(s) 924, operatively coupled together, and/or with other functional blocks, via bus 910.

The disk drive unit(s) 918 includes machine-readable medium(s) 926, on which is stored one or more sets of instructions 902 (e.g., software) embodying any one or more of the methodologies or functions herein, including those methods illustrated herein. The instructions 902 may also reside, completely or at least partially, within the program memory device(s) 906, the data memory device(s) 908, and/or the processing device(s) 904 during execution thereof by the computing system 900. The program memory device(s) 906 and the processing device(s) 904 also constitute machine-readable media. Dedicated hardware implementations, such as but not limited to ASICs, programmable logic arrays, and other hardware devices can likewise be constructed to implement methods described herein. Applications that include the apparatus and systems of various embodiments broadly comprise a variety of electronic and computer systems. Some embodiments implement functions in two or more specific interconnected hardware modules or devices with related control and data signals communicated between and through the modules, or as portions of an ASIC. Thus, the example system is applicable to software, firmware, and/or hardware implementations.

The term “processing device” as used herein is intended to include any processor, such as, for example, one that includes a CPU (central processing unit) and/or other forms of processing circuitry. Further, the term “processing device” may refer to more than one individual processor. The term “memory” is intended to include memory associated with a processor or CPU, such as, for example, RAM (random access memory), ROM (read only memory), a fixed memory device (for example, hard drive), a removable memory device (for example, diskette), a flash memory and the like. In addition, the display device(s) 912, input device(s) 914, cursor control device(s) 916, signal generation device(s) 920, etc., can be collectively referred to as an “input/output interface,” and is intended to include one or more mechanisms for inputting data to the processing device(s) 904, and one or more mechanisms for providing results associated with the processing device(s). Input/output or I/O devices (including but not limited to keyboards (e.g., alpha-numeric input device(s) 914, display device(s) 912, and the like) can be coupled to the system either directly (such as via bus 910) or through intervening input/output controllers (omitted for clarity).

In an integrated circuit implementation of one or more embodiments of the invention, multiple identical die are typically fabricated in a repeated pattern on a surface of a semiconductor wafer. Each such die may include a device described herein, and may include other structures and/or circuits. The individual dies are cut or diced from the wafer, then packaged as integrated circuits. One skilled in the art would know how to dice wafers and package die to produce integrated circuits. Any of the exemplary circuits or method illustrated in the accompanying figures, or portions thereof, may be part of an integrated circuit. Integrated circuits so manufactured are considered part of this invention.

An integrated circuit in accordance with the embodiments of the present invention can be employed in essentially any application and/or electronic system in which buffers are utilized. Suitable systems for implementing one or more embodiments of the invention include, but are not limited, to personal computers, interface devices (e.g., interface networks, high-speed memory interfaces (e.g., DDR3, DDR4), etc.), data storage systems (e.g., RAID system), data servers, etc. Systems incorporating such integrated circuits are considered part of embodiments of the invention. Given the teachings provided herein, one of ordinary skill in the art will be able to contemplate other implementations and applications.

In accordance with various embodiments, the methods, functions or logic described herein is implemented as one or more software programs running on a computer processor. Dedicated hardware implementations including, but not limited to, application specific integrated circuits, programmable logic arrays and other hardware devices can likewise be constructed to implement the methods described herein. Further, alternative software implementations including, but not limited to, distributed processing or component/object distributed processing, parallel processing, or virtual machine processing can also be constructed to implement the methods, functions or logic described herein.

The embodiment contemplates a machine-readable medium or computer-readable medium containing instructions 902, or that which receives and executes instructions 902 from a propagated signal so that a device connected to a network environment 922 can send or receive voice, video or data, and to communicate over the network 922 using the instructions 902. The instructions 902 are further transmitted or received over the network 922 via the network interface device(s) 924. The machine-readable medium also contains a data structure for storing data useful in providing a functional relationship between the data and a machine or computer in an illustrative embodiment of the systems and methods herein.

While the machine-readable medium 902 is shown in an example embodiment to be a single medium, the term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding, or carrying a set of instructions for execution by the machine and that cause the machine to perform anyone or more of the methodologies of the embodiment. The term “machine-readable medium” shall accordingly be taken to include, but not be limited to: solid-state memory (e.g., solid-state drive (SSD), flash memory, etc.); read-only memory (ROM), or other non-volatile memory; random access memory (RAM), or other re-writable (volatile) memory; magneto-optical or optical medium, such as a disk or tape; and/or a digital file attachment to e-mail or other self-contained information archive or set of archives is considered a distribution medium equivalent to a tangible storage medium. Accordingly, the embodiment is considered to include anyone or more of a tangible machine-readable medium or a tangible distribution medium, as listed herein and including art-recognized equivalents and successor media, in which the software implementations herein are stored.

It should also be noted that software, which implements the methods, functions and/or logic herein, are optionally stored on a tangible storage medium, such as: a magnetic medium, such as a disk or tape; a magneto-optical or optical medium, such as a disk; or a solid-state medium, such as a memory automobile or other package that houses one or more read-only (non-volatile) memories, random access memories, or other re-writable (volatile) memories. A digital file attachment to e-mail or other self-contained information archive or set of archives is considered a distribution medium equivalent to a tangible storage medium. Accordingly, the disclosure is considered to include a tangible storage medium or distribution medium as listed herein and other equivalents and successor media, in which the software implementations herein are stored.

Although the specification describes components and functions implemented in the embodiments with reference to particular standards and protocols, the embodiments are not limited to such standards and protocols.

The illustrations of embodiments described herein are intended to provide a general understanding of the structure of various embodiments, and they are not intended to serve as a complete description of all the elements and features of apparatus and systems that might make use of the structures described herein. Many other embodiments will be apparent to those of skill in the art upon reviewing the above description. Other embodiments are utilized and derived therefrom, such that structural and logical substitutions and changes are made without departing from the scope of this disclosure. Figures are also merely representational and are not drawn to scale. Certain proportions thereof are exaggerated, while others are decreased. Accordingly, the specification and drawings are to be regarded in an illustrative rather than a restrictive sense.

Such embodiments are referred to herein, individually and/or collectively, by the term “embodiment” merely for convenience and without intending to voluntarily limit the scope of this application to any single embodiment or inventive concept if more than one is in fact shown. Thus, although specific embodiments have been illustrated and described herein, it should be appreciated that any arrangement calculated to achieve the same purpose are substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In the foregoing description of the embodiments, various features are grouped together in a single embodiment for the purpose of streamlining the disclosure. This method of disclosure is not to be interpreted as reflecting that the claimed embodiments have more features than are expressly recited in each claim. Rather, as the following claims reflect, inventive subject matter lies in less than all features of a single embodiment. Thus, the following claims are hereby incorporated into the detailed description, with each claim standing on its own as a separate example embodiment.

The abstract is provided to comply with 37 C.F.R. § 1.72(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single embodiment. Thus, the following claims are hereby incorporated into the Detailed Description, with each claim standing on its own as separately claimed subject matter.

Although specific example embodiments have been described, it will be evident that various modifications and changes are made to these embodiments without departing from the broader scope of the inventive subject matter described herein. Accordingly, the specification and drawings are to be regarded in an illustrative rather than a restrictive sense. The accompanying drawings that form a part hereof, show by way of illustration, and without limitation, specific embodiments in which the subject matter are practiced. The embodiments illustrated are described in sufficient detail to enable those skilled in the art to practice the teachings herein. Other embodiments are utilized and derived therefrom, such that structural and logical substitutions and changes are made without departing from the scope of this disclosure. This Detailed Description, therefore, is not to be taken in a limiting sense, and the scope of various embodiments is defined only by the appended claims, along with the full range of equivalents to which such claims are entitled.

Given the teachings provided herein, one of ordinary skill in the art will be able to contemplate other implementations and applications of the techniques of the disclosed embodiments. Although illustrative embodiments have been described herein with reference to the accompanying drawings, it is to be understood that these embodiments are not limited to the disclosed embodiments, and that various other changes and modifications are made therein by one skilled in the art without departing from the scope of the appended claims.

What is claimed is:

1. A method of sputtering a layer on a substrate using a high energy density plasma (HEDP) magnetron, the method comprising:
positioning the HEDP magnetron in a vacuum chamber with a sputtering cathode target and the substrate;
providing feed gas;
applying a plurality of unipolar voltage pulses comprising high frequency voltage oscillations to a pulse forming network, the pulse forming network comprising a plurality of inductors and capacitors; and
adjusting an amplitude and a frequency associated with the plurality of unipolar voltage pulses to cause a resonance mode associated with the pulse forming network and an output AC voltage waveform generated from the pulse forming network, the output AC voltage waveform operatively coupled to the sputtering cathode target from the HEDP magnetron, the output AC voltage waveform comprising a negative voltage and a positive voltage, an increase in the amplitude of the unipolar voltage pulses causing an increase in amplitude of the positive voltage of the output AC voltage waveform in response to the pulse forming network being in the resonance mode, thereby causing the HEDP magnetron sputtering discharge to form the layer from the hollow cathode target material atoms and ions on the substrate.

2. The method, as defined by claim 1, further comprising applying a negative bias voltage to the substrate, thereby attracting positively charged sputtered hollow cathode target material ions to the substrate, a value of the negative bias voltage being in a range of about 0 V to 500 V.

3. The method, as defined by claim 1, wherein the sputtering cathode target comprises a hollow cathode shape.

4. The method, as defined by claim 1, wherein the feed gas comprises a noble gas, the noble gas comprising at least one of Ar, Ne, Kr, Xe, He.

5. The method, as defined by claim 1, wherein the feed gas comprises a mixture of a noble gas and a reactive gas, the reactive gas being reactive with target material atoms.

6. The method, as defined by claim 1, wherein the feed gas comprises a mixture of a noble gas and a gas that comprises cathode target material atoms.

7. The method as defined by claim 1, wherein the sputtering cathode target comprises a flat cathode target shape instead of hollow cathode target shape.

8. The method, as defined by claim 1, further comprising rotating the hollow cathode target magnet assembly at a speed in a range of 1 to 400 revolutions per minute.

9. The method, as defined by claim 1, wherein the substrate is a semiconductor wafer with a diameter in a range of 25 mm to 450 mm.

10. The method, as defined by claim 1, wherein the substrate is a razor blade.

11. The method, as defined by claim 1, wherein the substrate comprises a film used to manufacture a memory device.

12. The method, as defined by claim 1, further comprising providing the hollow cathode target material comprising at least one of the following elements: B, C, Al, Si, P, S, Ga, Ge, As, Se, In, Sn, Sb, Te, I, Tl, Pb, Bi, Sc, Ti, Cr, Mn, Fe, Co, Ni, Cu, Zn, Y, Zr, Nb, Mo, Tc, Ru, Rh, Pd, Ag, Cd, Lu, Hf, Ta, W, Re, Os, Ir, Pt, Au, La, Ce, Pr, Nd, Pm, Sm, Eu, Gd, Tb, Dy, Ho, Er, Tm, Yb, Be, Mg, Ca, Sr, Ba.

13. The method, as defined by claim 1, wherein the substrate is a part of car engine, the substrate comprising at least one of a valve, injector head, crank shaft, bushing, bearing, sprocket, cell phone, mobile phone, iPhone, iPod, touch screen.

14. The method, as defined by claim 1, wherein the substrate is at least one of a cutting tool, drill beat, insert for cutting tool.

15. An apparatus that sputters a layer on a substrate using a high energy density plasma (HEDP) magnetron, the apparatus comprising:
an anode;
a feed gas;
a HEDP magnetron comprising a hollow cathode target magnet assembly, the hollow cathode target assembly and the anode configured to be positioned in a vacuum chamber with the substrate;
a high-power pulse power supply, the high-power pulse power supply providing a plurality of unipolar negative voltage pulses with high frequency voltage oscillations comprising an amplitude and a frequency of unipolar negative voltage pulses;
and
a pulse forming network comprising a plurality of inductors and capacitors, the amplitude and the frequency of the plurality of unipolar negative voltage pulses comprising high frequency voltage oscillations adjusted to cause a resonance mode associated with the pulse forming network and an output AC voltage waveforms generated from the pulse forming network, the output AC voltage waveforms operatively coupled to the hollow cathode target assembly, the output AC voltage waveforms comprising a negative voltage and a positive voltage during sputtering discharge of the HEDP magnetron, an increase in the amplitude of the unipolar negative pulsed oscillatory voltage waveforms causing an increase in amplitude of the positive voltage of the output AC voltage waveform in response to the pulse forming network being in the resonance mode, thereby causing the HEDP magnetron sputtering discharge to form the layer from the hollow cathode target material atoms and ions on the substrate.

16. The apparatus, as defined by claim 15, further comprising a negative bias voltage power supply, the negative bias voltage power supply operatively coupling a negative bias voltage to the substrate, thereby attracting positively charged sputtered hollow cathode target material ions to the substrate, a value of the negative bias voltage being in a range of about 10 V to 500 V.

17. The apparatus, as defined by claim 15, wherein a value of a magnetic field disposed parallel to a surface of the hollow sputtering cathode target is in a range of about 150 G to 1000 G.

18. The apparatus, as defined by claim 15, wherein the feed gas comprises a noble gas, the noble gas comprising at least one of He, Ar, Kr, Xe, Ne.

19. The apparatus, as defined by claim 15, wherein the feed gas comprises a mixture of a noble gas and a reactive gas, the reactive gas.

20. The apparatus, as defined by claim 15, wherein the feed gas comprises a mixture of a noble gas and a gas that comprises cathode target material atoms.

21. The apparatus, as defined by claim 15, wherein the sputtering cathode target has a flat cathode target shape instead of hollow cathode target shape.

22. The apparatus, as defined by claim 15, wherein the magnet assembly rotates at a speed in a range of 1 to 400 revolutions per minute.

23. A method of sputtering a layer on a substrate using a high energy density plasma (HEDP) magnetron, the method comprising:
positioning an HEDP magnetron in a vacuum chamber with a sputtering cathode target and the substrate;
providing feed gas;
applying a pulsed AC voltage waveform comprising a frequency, amplitude, and duration to a pulse forming network, the pulse forming network comprising a step-up transformer, diode bridge, and a plurality of inductors and capacitors; and
adjusting an amplitude and a frequency associated with the pulsed AC voltage waveforms to cause a resonance mode associated with the pulse forming network and an output asymmetric high voltage AC waveform generated from the pulse forming network, the output asymmetric high voltage AC waveform operatively coupled to the sputtering cathode target from HEDP magnetron, the output asymmetric high voltage AC waveform comprising a negative voltage and a positive voltage, an increase in the amplitude of the unipolar voltage pulses causing an increase in amplitude of the positive voltage of the output AC voltage waveform in response to the pulse forming network being in the resonance mode, thereby causing the HEDP magnetron sputtering discharge to form the layer from the hollow cathode target material atoms and ions on the substrate.

24. The method, as defined by claim 23, further comprising applying a negative bias voltage to the substrate, thereby attracting positively charged sputtered hollow cathode target material ions to the substrate, a value of the negative bias voltage being in a range of about 0 V to 500 V.

25. The method, as defined by claim 23, wherein the sputtering cathode target comprises a hollow cathode shape.

26. A computer-readable medium storing instructions that, when executed by a processing device, perform a method of sputtering a layer on a substrate using a high energy density plasma (HEDP) magnetron, the operations comprising:
configuring an anode and a cathode target magnet assembly to be positioned in a vacuum chamber with a sputtering hollow cathode target and the substrate;
applying plurality of unipolar negative pulsed oscillatory voltage waveforms to a pulse forming network, the pulse forming network comprising a plurality of inductors and capacitors; and
adjusting an amplitude and a frequency associated with the plurality of unipolar negative pulsed oscillatory voltage waveforms to cause a resonance mode associated with the pulse forming network and an output AC voltage waveforms generated from the pulse forming network, the output AC voltage waveforms operatively coupled to the sputtering cathode target, the output AC voltage waveforms comprising a negative voltage exceeding an amplitude of the unipolar negative pulsed oscillatory voltage waveforms during sputtering discharge of the HEDP magnetron, an increase in the amplitude of the unipolar negative pulsed oscillatory voltage waveforms causing an increase in amplitude of the positive voltage of the output AC voltage waveform in response to the pulse forming network being in the resonance mode, thereby causing the HEDP magnetron sputtering discharge to form the layer from hollow cathode target material atoms and ions on the substrate.
